(19) United States
(12) Patent Application Publication
(10) Pub. No.: US 2017/0309858 A1
(43) Pub. Date: Oct. 26, 2017

(54) DISPLAY DEVICE

(71) Applicant: KONICA MINOLTA, INC., Tokyo (JP)

(72) Inventor: Kazuyoshi OMATA, Akishima-shi, Tokyo (JP)

(73) Assignee: KONICA MINOLTA, INC., Tokyo (JP)

(21) Appl. No.: 15/518,410

(22) PCT Filed: Oct. 20, 2015
(86) PCT No.: PCT/JP2015/079502

§ 371 Date: Apr. 11, 2017

(30) Foreign Application Priority Data
Oct. 21, 2014 (JP) 2014-214827

(51) Int. Cl. H01L 51/50; G02F 1/03; G02F 1/136

(52) U.S. Cl. CPC H01L 51/5044; H01L 51/5036; G02F 1/0316; G02F 1/136; H01L 51/5012

(57) ABSTRACT

A display device that is provided with a light-transmitting shutter element panel wherein shutter elements that control light transmission are arranged in a matrix and with a backlight panel that has organic electroluminescence elements and that is arranged so as to overlap the shutter element panel. The organic electroluminescence elements used in the display device are layered elements wherein light-emitting units of different colors are sandwiched between a plurality of electrodes and single-layer elements wherein a white light-emitting unit or a light-emitting unit of the complementary color of any of the different colors is sandwiched between a pair of electrodes. The layered elements and the single-layer elements are arranged so as to overlap the shutter elements in stripes that run parallel to the direction in which the shutter elements are arrayed.

### TECHNICAL FIELD

The present invention relates to a display device and particularly to a display device suitable for a field sequential type.

### BACKGROUND ART

A field-sequential type display device performing time-division color display has drawn attention in recent years. The field-sequential type display device is configured to sequentially light light-emitting elements of different colors in a time-division manner in accordance with driving of a pixel of a liquid crystal display panel by using the light-emitting elements in a plurality of colors as a backlight of the liquid crystal display panel and has a merit that an aperture ratio of a pixel is higher in comparison with conventional surface division.

In the display device as above, use of an organic electroluminescence element as a backlight is proposed. Patent Literature 1 described below, for example, describes “a field-sequential liquid crystal display device includes a transmission type liquid crystal panel and a backlight arranged on its rear surface side.” Moreover, it describes that “the backlight is constituted by a light emitting device including organic EL element in which three light-emitting units whose light emission colors are red, green, and blue are respectively layered on a substrate.”

### CITATION LIST

### Patent Literature

PTL 1: Japanese Patent Laid-Open No. 2007-172944

### SUMMARY OF INVENTION

### Technical Problem

However, the organic electroluminescence element used for the backlight of the display device described in cited literature 1 is configured by layering light-emitting units of three colors. Thus, light taking-out efficiency from the light-emitting unit arranged on a lower layer is not sufficient, and an increase of power consumption is concerned in order to obtain sufficient light-emitting efficiency for light emission of each color.

Thus, an object of the present invention is to provide a field-sequential type display device capable of lowering power consumption while reducing weight by using the organic electroluminescence element for the backlight.

### Solution to Problem

The display device for achieving the object as above includes a light-transmitting shutter element panel in which shutter elements that control light transmission are arranged in a matrix; and a backlight panel that has organic electroluminescence elements and that is arranged so as to overlap the shutter element panel, wherein layered elements in which light-emitting units of different colors are sandwiched between a plurality of electrodes and single-layer elements in which a white light-emitting unit or a light-emitting unit of the complementary color of any of the different colors is sandwiched between a pair of electrodes are used as the organic electroluminescence elements; and the layered elements and the single-layer elements are arranged so as to overlap the shutter elements in stripes that run parallel to a direction in which the shutter elements are arrayed.

### Advantageous Effects of Invention

According to the display device configured as above, it is possible to lower power consumption while reducing weight by using the organic electroluminescence element for the backlight.

### BRIEF DESCRIPTION OF DRAWINGS

FIG. 1 is a schematic plan view of an essential part for explaining planar configuration of a display device of a first embodiment.

FIG. 2 is a schematic sectional view of an essential part for explaining layered configuration of the display device of the first embodiment.

FIG. 3 is a schematic sectional view of a layered element provided in the display device.

FIG. 4 is a schematic sectional view of a single-layer element provided in the display device.

FIG. 5 is a timing chart for explaining a driving method of the display device of the first embodiment.

FIG. 6 is a schematic plan view of an essential part for explaining a modification of the first embodiment.

FIG. 7 is a schematic plan view of an essential part for explaining planar configuration of a display device of a second embodiment.

FIG. 8 is a schematic sectional view of an essential part for explaining layer configuration of the display device of the second embodiment.

FIG. 9 is a timing chart for explaining a driving method of the display device of the second embodiment.

FIG. 10 is a schematic plan view of an essential part for explaining a modification of the second embodiment.

### DESCRIPTION OF EMBODIMENTS

### First Embodiment

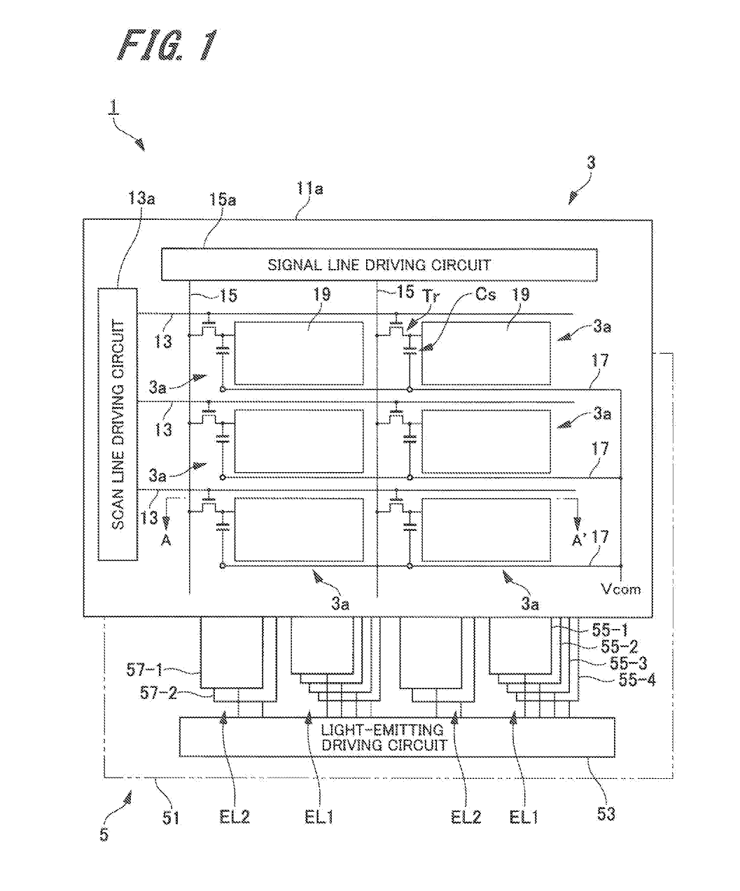

FIGS. 1 to 4 are views for explaining configuration of a display device 1 of a first embodiment to which the present invention is applied. The display device 1 illustrated in these figures is a so-called field-sequential type and has configuration in which a transmission type shutter element panel 3 and a backlight panel 5 using an organic electroluminescence element are layered. Hereinafter the configuration of the display device 1 will be described in order of planar configuration of the shutter element panel 3, layer configuration of the shutter element panel 3, planar configuration of the backlight panel 5, layer configuration of the backlight panel 5, and a driving method of the display device 1.

### <Planar Configuration of Shutter Element Panel 3>

FIG. 1 is a schematic plan view of an essential part for explaining the planar configuration of the display device 1 of the first embodiment. The shutter element panel 3 in the display device 1 illustrated in the view is a liquid crystal display panel, for example, in which a liquid crystal layer is sandwiched between two substrates. Note that, a plan view of one of the substrates (first substrate 11a) is illustrated as the shutter element panel 3 in FIG. 1.

A plurality of scan lines 13 is wired in a row direction (horizontal direction, here) on the first substrate 11a of the shutter element panel 3, a plurality of signal lines 15 is wired in a column direction (perpendicular direction), and one shutter element 3a is provided at each of intersection portions thereof.

Moreover, common wirings 17 are wired in parallel with the scan lines 13 on the first substrate 11a. Moreover, on a peripheral edge portion on the first substrate 11a, a scan line driving circuit 13a for scan-driving the scan lines 13 and a signal line driving circuit 15a for supplying a video signal (that is, an input signal) corresponding to brightness information to the signal lines 15 are arranged.

A shutter opening/closing circuit including a thin film transistor Tr and a holding capacitor Cs, for example, is provided at each shutter element 3a, and pixel electrodes 19 are connected to these opening/closing circuits. The opening/closing circuit is a so-called pixel circuit. Note that the pixel electrode 19 is assumed to be provided on an inter-layer insulating film covering the opening/closing circuit as will be described in detail by use of a plan view and a sectional view later.

Each thin film transistor Tr has a gate electrode connected to the scan line 13, a source electrode connected to the signal line 15, and a drain electrode connected to the holding capacitor Cs and the pixel electrode 19. Here, the thin film transistor Tr of each of the shutter elements 3a arranged along the scan line 13 connects the gate electrode to scan line 13 in a state sharing the one scan line 13. Further, the other electrode of the holding capacitor Cs is connected to the common wiring 17. Note that the common wiring 17 is connected to a common electrode on the second substrate side, not shown, here.

With this configuration, a video signal written from the signal line 15 through the thin film transistor Tr is held in the holding capacitor Cs, and a voltage corresponding to a held signal amount is supplied to each of the pixel electrodes 19.

The configuration of the opening/closing circuit as above is only an example, and a capacitor element may be provided in the opening/closing circuit as necessary or the opening/closing circuit may be configured by provision of a plurality of the transistors. A necessary driving circuit may be further added in accordance with a change of the opening/closing circuit in a peripheral area of the first substrate 11a.

Note that, in the views, the configuration in which the shutter elements 3a in three rows and two columns are arranged on the first substrate 11a is illustrated, but in an actual display device, a necessary number of the shutter elements 3a are arranged both in the row direction and in the column direction. The shutter element panel 3 is not limited to the liquid crystal display panel but may be an element panel whose optical aperture can be freely opened/closed in each pixel. Such a shutter element panel may be a MEMS shutter element panel in which a micro machine (Micro Electro Mechanical Systems: MEMS) shutter is incorporated in each pixel, for example.

### <Layer Configuration of Shutter Element Panel 3>

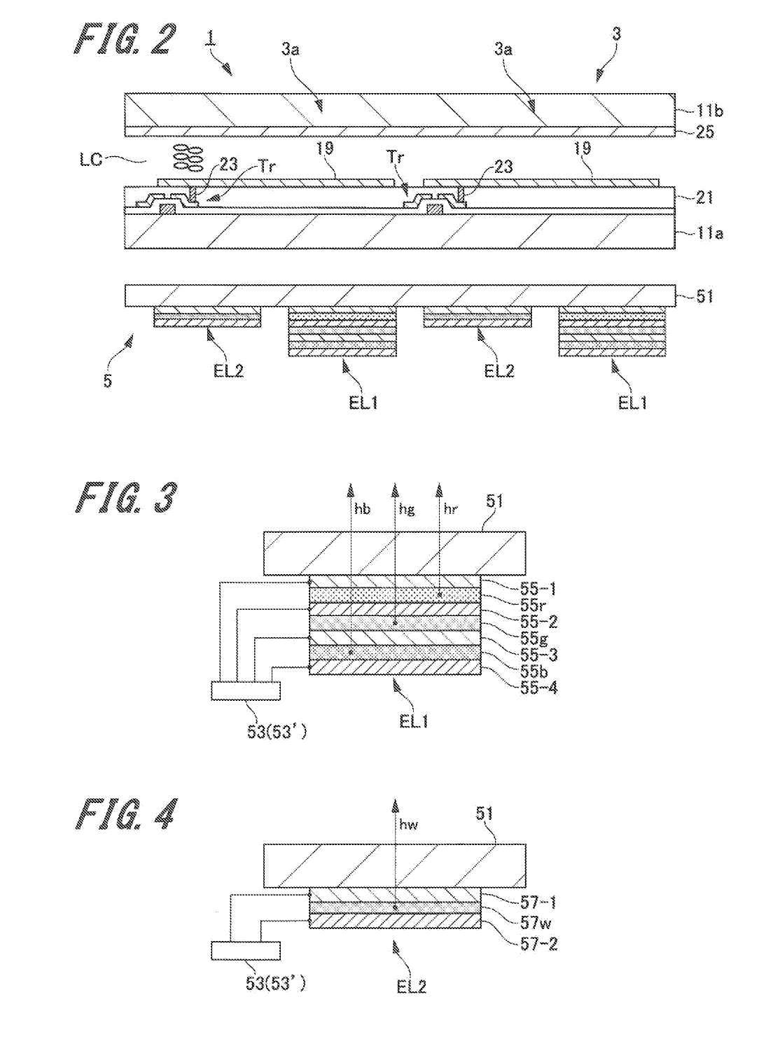

FIG. 2 is a schematic sectional view of an essential part for explaining the layer configuration of the display device 1 of the first embodiment and is a view corresponding to an A-A′ section in FIG. 1. As illustrated in the view, in the shutter element panel 3, a liquid crystal layer LC is sandwiched between the first substrate 11a and a second substrate 11b made of a transparent material such as a glass substrate or a plastic substrate. The circuit described by use of FIG. 1 is formed on the first substrate 11a in them.

The thin film transistor Tr and the capacitor element, the scan line, the signal line, and the common wiring (for them, see FIG. 1), not shown, here, are provided on a plane facing the liquid crystal layer LC side of the first substrate 11a. They are covered by an inter-layer insulating film 21. The pixel electrodes 19 are arranged/formed on a top part of the inter-layer insulating film 21. Each of the pixel electrodes 19 is constituted by a conductive material having light permeability and is connected to the drain electrode of the thin film transistor Tr through a connection hole 23 provided in the inter-layer insulating film 21.

A surface side on which the pixel electrode 19 is formed in the first substrate 11a on a driving side as above is covered by an oriented film, not shown, here, and the liquid crystal layer LC is provided through the oriented film.

On the other hand, a common electrode 25 is provided on a surface facing the liquid crystal layer LC side of the second substrate 11b arranged opposite to the first substrate 11a through the liquid crystal layer LC. The common electrode 25 is constituted by a conductive material having light permeability and is provided in a solid film state having a potential common with all the shutter elements 3a. Further, the surface side on which the common electrode 25 is formed in the second substrate 11b is covered by the oriented film, not shown, here, and the liquid crystal layer LC is provided through the oriented film.

The liquid crystal layer LC provided between the oriented film on the first substrate 11a and the oriented film of the second substrate 11b as above includes a liquid crystal molecule driven by on/off of the pixel electrode 19. A layer thickness of the liquid crystal layer LC is assumed to be held to a predetermined layer thickness (cell gap) by provision of a spacer (not shown) sandwiched between the first substrate 11a and the second substrate 11b.

Then, a pair of deflecting plates, not shown, here, are arranged on outer sides of the first substrate 11a and the second substrate 11b above, and the backlight panel 5 is arranged on the outer side of the deflecting plate on the first substrate 11a side so as to constitute the display device 1.

### <Planar Configuration of Backlight Panel 5>

As illustrated in FIG. 1, the backlight panel 5 includes organic electroluminescence elements and is arranged on the first substrate 11a side in the shutter element panel 3. The backlight panel 5 includes layered elements EL1 and single-layer elements EL2 on one major surface of a transparent substrate 51. Here, it is configured as an example such that the layered elements EL1 and the single-layer elements EL2 are arranged on a surface on a side opposite to the shutter element panel 3 in the transparent substrate 51.

The layered elements EL1 and the single-layer elements EL2 are arranged on the transparent substrate 51 in stripes that run parallel to the direction in which the shutter elements 3a are arrayed in the shutter element panel 3 and are extended in the column direction (perpendicular direction) along the signal line 15 provided on the shutter element panel 3, for example. Further, the layered elements EL1 and the single-layer elements EL2 are alternately arranged in the row direction (perpendicular direction) along the scan line 13.

Particularly, it is so configured that a pair of the layered element EL1 and the single-layer element EL2 are arranged at each column of the shutter elements 3a. Note that, for explanation, a state where the shutter element panel 3 and the backlight panel 5 are shifted is illustrated in FIG. 1, but the pair of layered element EL1 and the single-layer element EL2 are layered with respect to each of the shutter elements 3a in arrangement.

Further a light-emitting driving circuit 53 for driving the layered elements EL1 and the single-layer elements EL2 is connected to the transparent substrate 51. The light-emitting driving circuit 53 individually supplies a voltage for controlling light emission of each of the light-emitting units to a first electrode 55-1 to a fourth electrode 55-4 of the layered element EL1 and a first electrode 57-1 and a second electrode 57-2 of the single-layer element EL2 which will be described later in detail.

### <Layer Configuration of Backlight Panel 5>

As illustrated in FIGS. 1 and 2, the backlight panel 5 has configuration in which the layered elements EL1 and the single-layer elements EL2 are arranged on a surface on a side opposite to the shutter element panel 3 in the transparent substrate 51 such as a glass substrate or a plastic substrate. Emission light obtained by the layered element EL1 and the single-layer element EL2 is taken out to the shutter element panel 3 side through the transparent substrate 51. Configuration of the layered element EL1 and the single-layer element EL2 is as follows.

### [Layered Element EL1]

FIG. 3 is a schematic sectional configuration view of the layered element EL1. As illustrated in the view, the layered element EL1 has a first electrode 55-1, a second electrode 55-2, a third electrode 55-3, and a fourth electrode 55-4, for example, in order from the transparent substrate 51 side. Light-emitting units of different light emission colors are sandwiched between these electrodes.

As an example, a red light-emitting unit 55r is sandwiched between the first electrode 55-1 and the second electrode 55-2. Either one of the first electrode 55-1 and the second electrode 55-2 functions as an anode with respect to the red light-emitting unit 55r, while the other functions as a cathode. The red light-emitting unit 55r is configured to obtain emission light hr of red (R) by recombination between a positive hole injected from the anode and an electron injected from the cathode.

Moreover, a green light-emitting unit 55g is sandwiched between the second electrode 55-2 and the third electrode 55-3. Either one of the second electrode 55-2 and the third electrode 55-3 functions as an anode with respect to the green light-emitting unit 55g, while the other functions as a cathode. The green light-emitting unit 55g is configured to obtain emission light hg of green (G) by recombination between a positive hole injected from the anode and an electron injected from the cathode.

Furthermore, a blue light-emitting unit 55b is sandwiched between the third electrode 55-3 and the fourth electrode 55-4. Either one of the third electrode 55-3 and the fourth electrode 55-4 functions as an anode with respect to the blue light-emitting unit 55b, while the other functions as a cathode. The blue light-emitting unit 55b is configured to obtain emission light hb of blue (B) by recombination between a positive hole injected from the anode and an electron injected from the cathode.

In the first electrode 55-1 to the fourth electrode 55-4 as above, the first electrode 55-1, the second electrode 55-2, and the third electrode 55-3 which the emission lights hr, hg, and hb obtained in the light-emitting units 55r, 55g, and 55b transmit, respectively, are constituted by use of a conductive material having light permeability. Oxide semiconductors such as ITO (indium-tin oxide), ZnO (zinc oxide), TiO₂ (titanium oxide), SnO₂ (tin oxide), IZO (registered trademark: indium zinc oxide) and moreover, silver (Ag) in a thin-film state to such a degree that has light permeability are used as the conductive material having such light permeability.

Particularly, these first electrode 55-1, the second electrode 55-2, and the third electrode 55-3 are preferably constituted by a silver thin film which has low resistance but sufficient light permeability. When the silver thin film is used, a layer which can ensure film-forming uniformity of the silver thin film such as a nitrogen-containing layer is preferably provided as its film-forming base layer. Such a layer preferably functions both as a positive hole-injecting layer and as an electron injecting layer, for example, as a part of the light-emitting unit. Note that the silver thin film is preferably used as an anode.

On the other hand, the fourth electrode 55-4 is constituted by use of a conductive material having light reflectivity. As the conductive material having such light reflectivity, a metal material such as aluminum is used, and a material considering a work function is selected from among these materials and used.

Further, entire layer configuration of the red light-emitting unit 55r, the green light-emitting unit 55g, and the blue light-emitting unit 55b is not limited as a light-emitting unit of the organic electroluminescence element. Configuration in which [positive hole-injecting layer/positive hole transport layer/light-emitting layer/electron transport layer/electron injecting layer] are layered in order from the anode side is exemplified as an example. It is indispensable to have the light-emitting layer constituted by use of at least an organic material in them. The positive hole-injecting layer and the positive hole transport layer may be provided as a positive hole transport/injecting layer. The electron transport layer and the electron injecting layer may be provided as an electron transport/injecting layer.

Moreover, in the red light-emitting unit 55r, the green light-emitting unit 55g, and the blue light-emitting unit 55b, a layering order from the transparent substrate 51 side is not limited, and it is only necessary that they are arranged in the layering order suitable for the respective characteristics. Moreover, the light-emitting units of different colors constituting the layered element EL1 are not limited to the red light-emitting unit 55r, the green light-emitting unit 55g, and the blue light-emitting unit 55b, but those which can obtain emission light of complementary colors of them or those emitting RGB lights may be layered or the light-emitting units emitting respective complementary colors of RGB may be layered.

The layered element EL1 as above can freely emit the emission light hr of red (R), emission light hg of green (G), and the emission light hb of blue (B) by controlling the voltage to be supplied to the first electrode 55-1 to the fourth electrode 55-4 by the light-emitting driving circuit 53.

### [Single-Layer Element EL2]

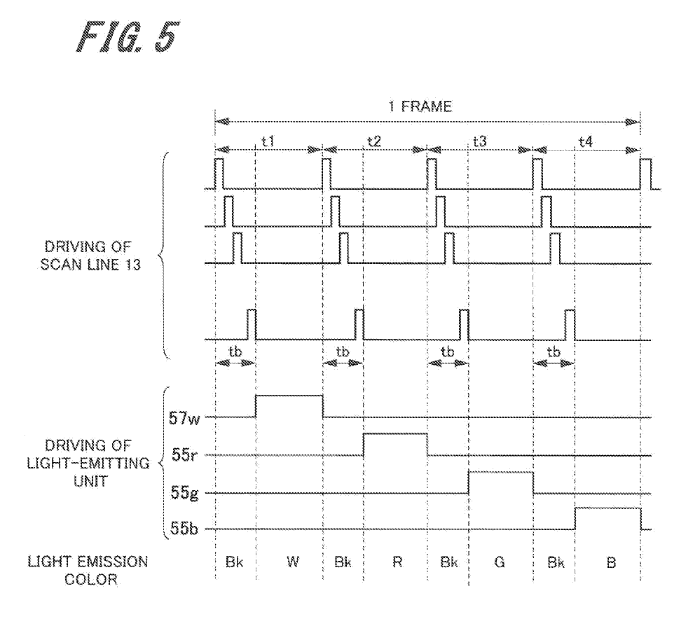

FIG. 4 is a schematic sectional configuration diagram of the single-layer element EL2. As illustrated in the figure, the single-layer element EL2 has the first electrode 57-1 and the second electrode 57-2 layered in order from the transparent substrate 51 side, for example. A white light-emitting unit 57w is sandwiched between these electrodes.

Either one of the first electrode 57-1 and the second electrode 57-2 functions as an anode with respect to the white light-emitting unit 57w, while the other functions as a cathode. The white light-emitting unit 57w is configured to obtain emission light hw of white (W) by recombination between a positive hole injected from the anode and an electron injected from the cathode.

Moreover, the first electrode 57-1 transmitting the emission light obtained in the white light-emitting unit 57w among them is constituted by use of a conductive material having light permeability. As the conductive material having such light permeability, those similar to the first electrode 55-1 of the layered element EL1 is used similarly. On the other hand, the second electrode 57-2 is constituted by use of a conductive material having light reflectivity. As the conductive material having such light reflectivity, those similar to the fourth electrode 55-4 of the layered element EL1 is used similarly.

Moreover, it is only necessary that the white light-emitting unit 57w is constituted so that the emission light hw of white (W) is obtained. A color temperature of the emission light hw takes a value in a range from 2000K to 12000K. Such white light-emitting unit 57w may be constituted by layering of the light-emitting units which can obtain emission lights of complementary colors to each other through an intermediate layer. Regarding the configuration of each light-emitting unit, an entire layer structure is not limited as the light-emitting unit of the organic electroluminescence element but is similar to that of the layered element EL1.

The single-layer element EL2 as above can freely emit the emission light hw of white (W) by control of the voltage to be supplied to the first electrode 57-1 and the second electrode 57-2 by the light-emitting driving circuit 53.

Note that, in the above, any one of the electrodes of the layered type EL1 and either one of the electrodes of the single-layer element EL2 may be provided as common electrodes. For example, the first electrode 55-1 of the layered element EL1 and the first electrode 57-1 of the single-layer element EL2 may be provided as common electrodes or the fourth electrode 55-4 of the layered element EL1 and the second electrode 57-2 of the single-layer element EL2 may be provided as common electrodes.

Moreover, in each layer constituting the layered element EL1 and the single-layer element EL2 constituted as above, a forming method thereof is not limited but an appropriate method such as a vapor deposition method or an application method is employed. Moreover, each light-emitting unit of the layered element EL1 and the single-layer element EL2 has a light-emitting layer constituted by use of at least an organic material. Thus, it is assumed that the layer is sealed by a sealing member, not shown, here, but its sealing structure is not limited but the layer may have a hollow structure or a sealant-filled structure.

### <Driving Method of Display Device 1>

FIG. 5 is a timing chart for explaining a driving method of the display device 1 and illustrates a period of 1 frame. The driving method of the display device 1 will be described below with reference to FIGS. 1 to 4 above together with FIG. 5. Note that, in the timing chart for driving of the scan line 13, a high-period is an on-state of a gate of the thin film transistor Tr, and in the timing chart for driving of the light-emitting unit, a high-period indicates a light emission period of each light-emitting unit, in FIG. 5.

First, the scan line driving circuit 13a in the shutter element panel 3 sequentially supplies a row selection signal to the scan line 13 at each of a first period t1 to a fourth period t4 obtained by dividing 1 frame. As a result, in each of the first period t1 to the fourth period t4, the shutter element 3a is sequentially selected for each row. Here, the number of divisions in 1 frame is assumed to correspond to the number of light emission colors of the light-emitting units provided in the backlight panel 5 (here, four colors, that is, W, R, G, and B). Each of the first period t1 to the fourth period t4 is a period assigned to the light emission colors of the light-emitting units provided in the backlight panel 5.

On the other hand, the signal line driving circuit 15a sequentially supplies a video signal corresponding to the brightness information to each signal line 15 in accordance with timing of supply of the row selection signal to the scan line 13.

As a result, a voltage corresponding to the signal amount supplied from each of the signal lines 15 is applied to the pixel electrode 19 of each of the shutter elements 3a connected to the selected scan line 13, and the shutter of each of the shutter elements 3a is opened in accordance with the voltage. Here, a liquid crystal molecule of the liquid crystal layer LC corresponding to each of the pixel electrode 19 portions is tilted in accordance with the voltage applied to the pixel electrode 19, whereby the shutter element 3a is opened at an aperture ratio corresponding to the signal amount supplied from each of the signal lines 15.

Then, when selection of all the scan lines 13 by the scan line driving circuit 13a is finished in one period (the first period t1, for example), all the shutter elements 3a are in an open state according to the signal amount supplied from each of the signal lines 15.

On the other hand, the backlight panel 5 is driven as follows within a period of 1 frame. That is, the light-emitting driving circuit 53 sequentially causes each of the light-emitting units of the layered element EL1 and the single-layer element EL2 to emit light in the first period t1 to the fourth period t4 obtained by dividing 1 frame in order of the light emission colors assigned to the first period t1 to the fourth period t4.

If the emission light of white (W) is assigned to the first period t1, for example, the white light-emitting unit 57w of the single-layer element EL2 is made to emit light in the first period t1. Similarly, the red light-emitting unit 55r of the layered element EL1 is made to emit light in the second period t2, the green light-emitting unit 55g is made to emit light in the third period t3, and the blue light-emitting unit 55b is made to emit light in the fourth period t4. Note that the light emission of each of the light-emitting units may be handled by so-called local dimming in which brightness at each light emission is controlled in accordance with the video signal corresponding to the brightness information supplied to the signal line driving circuit 15a of the shutter element panel 3.

The emission lights hw, hr, hg, and hb generated in the first period t1 to the fourth period t4 respectively transmit the shutter element 3a in accordance with the aperture ratio of the shutter element 3a in the first period t1 to the fourth period t4.

As a result, a feed-sequential type driving displayed in time division is performed on the emission light hw of white (W), the emission light hr of red (R), the emission light hg of green (G), and the emission light hb of blue (B), in the period of 1 frame.

Note that the light-emitting driving circuit 53 sets a period during which the scan line on the first row to the scan line on the last row have been selected in the first period t1 to the fourth period t4 to a blank period tb and stops light emission in the light-emitting unit in the blank period tb. As a result, the blank period tb gives black display (Bk) in all the shutter elements, and a transmission amount of each color is prevented from being different in each row of the shutter elements. Further, a portion corresponding to the one shutter element 3a becomes one pixel in the driving.

### Advantages of First Embodiment

The display device 1 as above has configuration in which the backlight panel 5 having organic electroluminescence elements provided so as to overlap the shutter element panel 3 is provided and thus, size reduction and thinning of a frame can be achieved.

Moreover, the display device 1 has configuration provided with the single-layer element EL2 including the white light-emitting unit 57w, in addition to the layered element EL1 including the red light-emitting unit 55r, the green light-emitting unit 55g, and the blue light-emitting unit 55b, as organic electroluminescence elements. As a result, brightness of the entire display screen can be improved, and power consumption can be reduced as compared with a case where only the light emission of emission light hr of red (R), the emission light hg of green (G), and the emission light hb of blue (B) is used. Moreover, by provision of the single-layer element EL2 including the white light-emitting unit 57w separately from the layered element EL1, the light emission of the emission light of different colors from the red light-emitting unit 55r, the green light-emitting unit 55g, and the blue light-emitting unit 55b is not prevented, whereby further reduction of power consumption can be achieved.

As a result, even if the display device 1 is used particularly as a display unit of a smart device whose battery capacity tends to run short, driving time of the device can be improved.

### Modification of First Embodiment

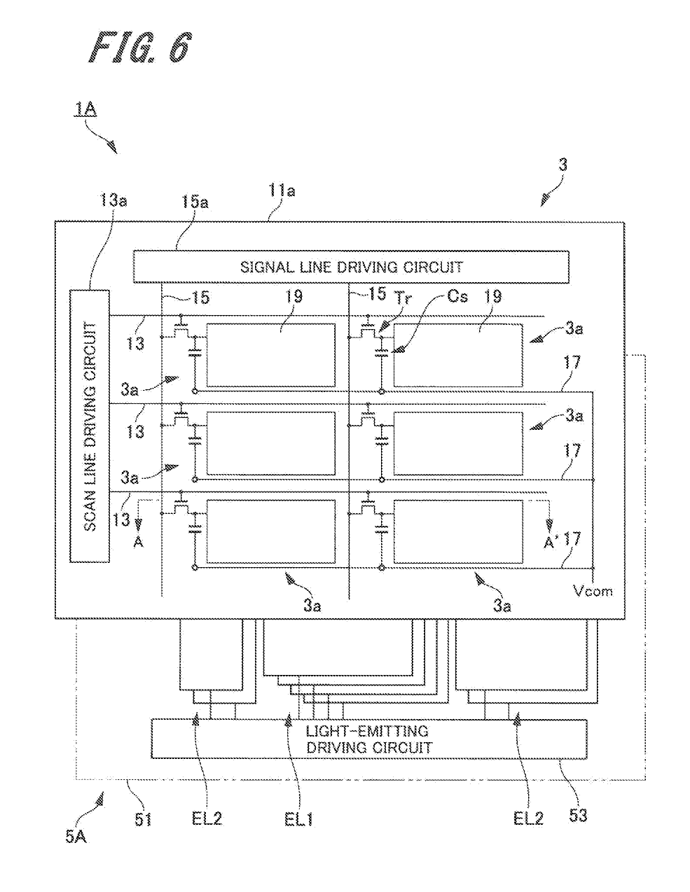

FIG. 6 is a schematic plan view of an essential part for explaining a modification of the first embodiment. A display device 1A illustrated in the figure is different from the display device 1 in the first embodiment in configuration of a backlight panel 5A. That is, in the backlight panel 5A, the layered element EL1 is arranged as a common element between columns of the shutter elements 3a arranged adjacent to each other in the row direction and the single-layer element EL2 is arranged as a common element. The other configuration is similar to the first embodiment including the driving method.

With configuration of such modification, sizes of patterns of the layered element EL1 and the single-layer element EL2 can be increased, and miniaturization of the pixel can be handled more easily.

### Second Embodiment

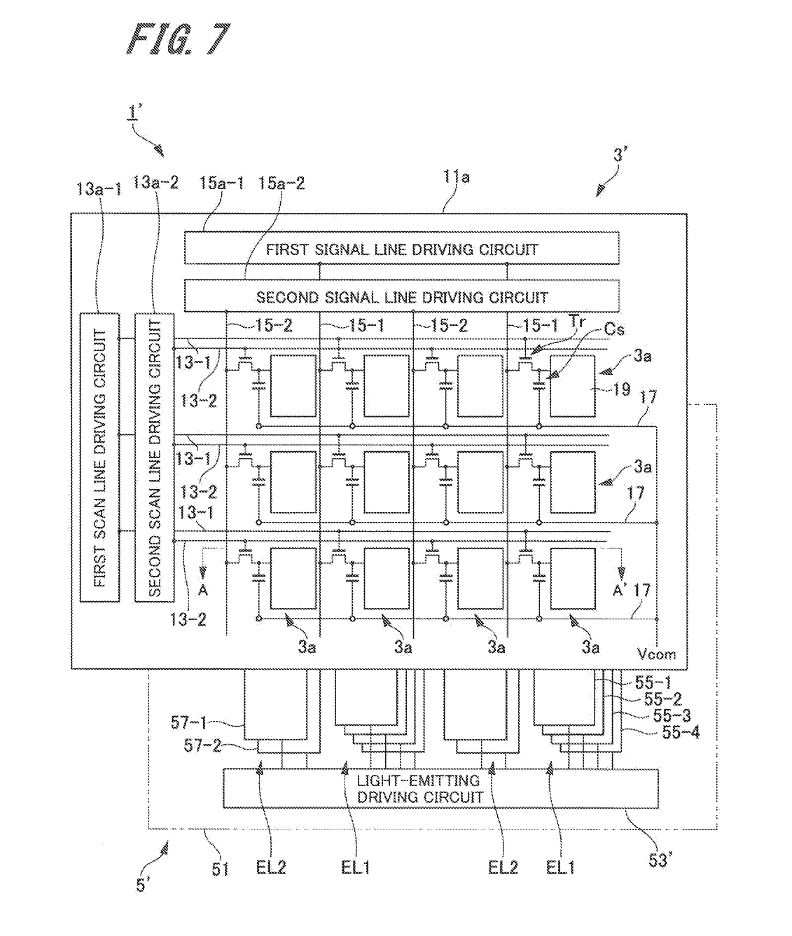

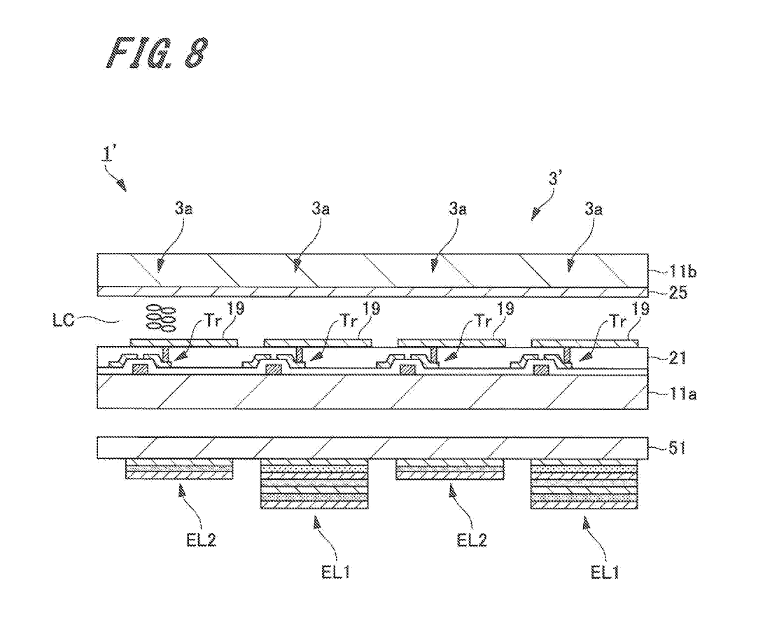

FIGS. 7 and 8 are views for explaining configuration of a display device 1′ of a second embodiment to which the present invention is applied. The display device 1′ illustrated in these views is different from the display device of the first embodiment explained by use of FIGS. 1 to 5 is the planar configuration of a shutter element panel 3′, a selection procedure of the scan line by the scan line driving circuit 13a, and light emission control by a light-emitting driving circuit 53′. The shutter element 3a, the layered element EL1, the single-layer element EL2, and the other configuration are similar to those of the first embodiment. Thus, the same reference numerals are given to constituent elements similar to those of the first embodiment below and duplicated explanation will be omitted.

### <Planar Configuration of Shutter Element Panel 3′>

FIG. 7 is a schematic plan view of an essential part for explaining planar configuration of the display device 1′ of the second embodiment. As illustrated in the figure, a first scan line 13-1 and a second scan line 13-2 make a pair, and a plurality of pairs of the first scan line 13-1 and the second scan line 13-2 are wired in the row direction (horizontal direction, here) on the first substrate 11a of the shutter element panel 3′. A pair of the first scan line 13-1 and the second scan line 13-2 are wired close to each other.

Moreover, a first signal line 15-1 and a second signal line 15-2 make a pair, and a plurality of pairs of the first signal line 15-1 and the second signal line 15-2 are wired in the column direction (perpendicular direction) on the first substrate 11a. A pair of the first signal line 15-1 and the second signal line 15-2 are wired at such an interval that the shutter elements 3a are arranged between them, and the first signal line 15-1 and the second signal line 15-2 are wired alternately, here.

Then, one shutter element 3a is provided at each of intersection portions where the first scan line 13-1 and the second scan line 13-2 cross the first signal line 15-1. Similarly, one shutter element 3a is provided at each of intersection portions where the first scan line 13-1 and the second scan line 13-2 cross the second signal line 15-2. Other than above, a common wiring 17 is wired in parallel with the first scan line 13-1 and the second scan line 13-2 on the first substrate 11a.

Moreover, on a peripheral edge portion on the first substrate 11a, a first scan line driving circuit 13a-1 for driving the first scan line 13-1, a second scan line driving circuit 13a-2 for driving the second scan line 13-2, a first signal line driving circuit 15a-1 for supplying a video signal (that is, an input signal) corresponding to the brightness information to the first signal line 15-1, and a second signal line driving circuit 15a-2 for supplying it to the second signal line 15-2 are arranged.

Configuration of each of the shutter elements 3a is similar to that of the first embodiment, including the opening/closing circuit. However, the shutter elements 3a are arranged in a state where one row of the shutter elements 3a is layered on one layered element EL1 in the backlight panel 5′ and one row of the shutter elements 3a is layered on one single-layer element EL2.

In the shutter elements 3a above, the shutter elements 3a arranged so as to overlap the layered element EL1 are connected to the first scan line 13-1 and the first signal line 15-1. On the other hand, the shutter elements 3a arranged so as to overlap the single-layer element EL2 are connected to the second scan line 13-2 and the second signal line 15-2.

As a result, in the shutter elements 3a arranged in a matrix on the first substrate 11a, the shutter elements 3a arranged in a row direction in parallel with the first scan line 13-1 and the second scan line 13-2 are connected alternately to the first scan line 13-1 and the second scan line 13-2 and are connected alternately to the first signal line 15-1 and the second signal line 15-2.

### <Layer Configuration of Shutter Element Panel 3′>

FIG. 8 is a schematic sectional view of an essential part for explaining layer configuration of the display device 1′ of the second embodiment and a view corresponding to an A-A′ section in FIG. 7. As illustrated in the figure, the layer configuration of the shutter element panel 3′ of the second embodiment is similar to the layer configuration of the shutter element panel of the first embodiment. However, one shutter element 3a is arranged so as to overlap only one layered element EL1 or one single-layer element EL2 in the backlight panel 5′.

### <Planar Configuration and Layer Configuration of Backlight Panel 5′>

As illustrated in FIGS. 7 and 8, the planar configuration and the layer configuration of the backlight panel 5′ are similar to those of the first embodiment. Moreover, configurations of the layered element EL1 and the single-layer element EL2 are similar to the configuration described by use of FIGS. 3 and 4 in the first embodiment. However, the layered elements EL1 and the single-layer elements EL2 are arranged alternately in each column of the shutter elements 3a. However, the driving procedure of the layered element EL1 and the single-layer element EL2 by the light-emitting driving circuit 53′ is different from that of the first embodiment as will be described later.

### <Driving Method of Display Device 1′>

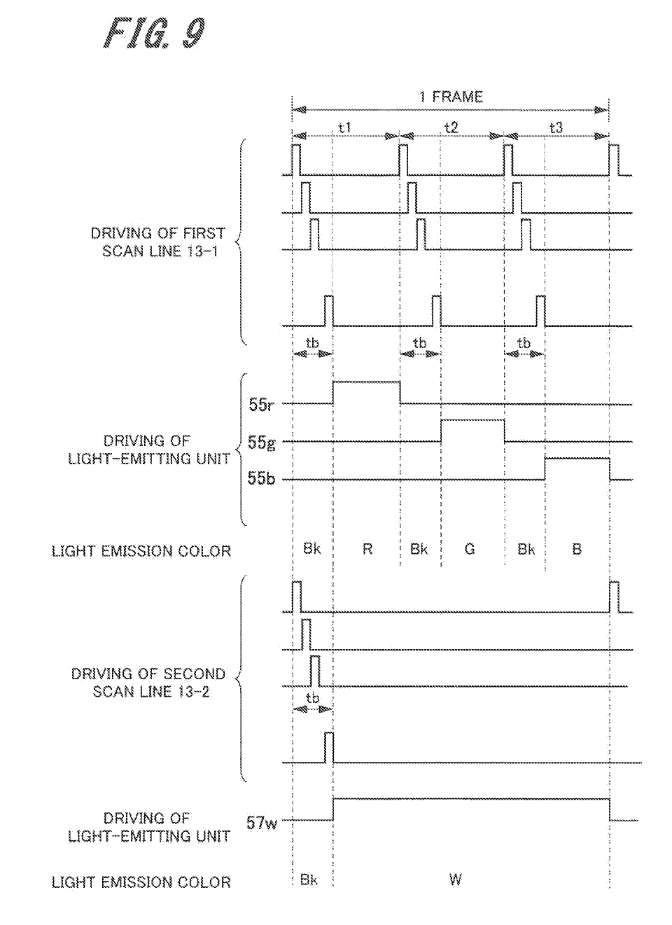

FIG. 9 is a timing chart for explaining the driving method of the display device 1′ and illustrates a period of 1 frame. The driving method of the display device 1′ will be described below with reference to FIGS. 3 to 4 above and FIGS. 7 to 8 together with FIG. 9. Note that, in FIG. 9, the timing chart for driving of the first scan line 13-1 and driving of the second scan line 13-2 indicates that a high-period is an on-state of a gate of the thin film transistor Tr, and the timing chart of the light-emitting unit indicates that a high-period is a light-emitting period of each light-emitting unit.

First, the first scan line driving circuit 13a-1 in the shutter element panel 3′ sequentially supplies a row selection signal to the first scan line 13-1 at each of a first period t1 to a third period t3 obtained by dividing 1 frame. As a result, in each of the first period t1 to the third period t3, the shutter element 3a layered on the layered element EL1 is sequentially selected for each row. Here, the number of divisions in 1 frame is assumed to correspond to the number of light emission colors of the light-emitting units provided in the layered element EL1 of the backlight panel 5′ (here, three colors, that is, R, G, and B). Each of the first period t1 to the third period t3 is a period assigned to the light emission colors of the light-emitting units provided in the layered element EL1.

Moreover, the second scan line driving circuit 13a-2 sequentially supplies the row selection signal to the second scan line 13-2 at each 1 frame. As a result, the shutter element 3a layered on the single-layer element EL2 is sequentially selected at each row in 1 frame.

On the other hand, the first signal line driving circuit 15a-1 sequentially supplies the video signal corresponding to the brightness information to each of the first signal lines 15-1 in accordance with timing of supply of the row selection signal to the first scan line 13-1. At this time, the video signal is supplied from the first signal line 15-1 at each of the first period t1 to the third period t3 obtained by dividing 1 frame.

Moreover, the second signal line driving circuit 15a-2 sequentially supplies the video signal corresponding to the brightness information to each of the second signal lines 15-2 in accordance with timing of supply of the row selection signal to the second scan line 13-2. At this time, the video signal is supplied from the signal line 15 at each 1 frame.

As a result, a voltage corresponding to the signal amount supplied from the first signal line 15-1 or the second signal line 15-2 is applied to the pixel electrode 19 of each of the shutter elements 3a connected to the selected first scan line 13-1 and the second scan line 13-2, and the shutter of each of the shutter elements 3a is opened in accordance with the voltage. Here, a liquid crystal molecule of the liquid crystal layer LC corresponding to each of the pixel electrode 19 portions is tilted in accordance with the voltage applied to the pixel electrode 19, whereby it is opened in accordance with the signal amount supplied from each of the signal lines 15.

At this time, the shutter element 3a to which the first scan line 13-1 is connected and which is connected to the layered element EL1 changes its open state in accordance with the signal amount at each of the first period t1 to the third period t3 obtained by dividing 1 frame. On the other hand, the shutter element 3a to which the second scan line 13-2 is connected and which is connected to the single-layer element EL2 changes its open state in accordance with the signal amount at each 1 frame.

On the other hand, the backlight panel 5′ is driven as follows in a period of 1 frame. That is, the light-emitting driving circuit 53′ sequentially causes each of the light-emitting units of the layered element EL1 to emit light in the first period t1 to the third period t3 of 1 frame in order of the light emission colors assigned to the first period t1 to the third period t3.

If the light emission of red (R) is assigned to the first period t1, for example, the red light-emitting unit 55r of the layered element EL1 is made to emit light in the first period t1. Similarly, the green light-emitting unit 55g of the layered element EL1 is made to emit light in the second period t2, and the blue light-emitting unit 55b is made to emit light in the third period t3. The light emission of each of the light-emitting units may be handled by so-called local dimming in which brightness at each light emission is controlled in accordance with the video signal corresponding to the brightness information supplied to the first signal line driving circuit 15a-1 and the second signal line driving circuit 15a-2 of the shutter element panel 3′.

The emission lights hr, hg, and hb generated from the layered element EL1 in the first period t1 to the third period t3 transmit the shutter element 3a in accordance with the aperture ratio of the shutter element 3a in the first period t1 to the third period t3, respectively.

Moreover, the light-emitting driving circuit 53′ sequentially causes each of the light-emitting units of the layered element EL1 to emit light in a period of 1 frame and causes the white light-emitting unit 57w of the single-layer element EL2 to emit light.

In the period of 1 frame, the emission light hw generated from the single-layer element EL2 transmits the shutter element 3a in accordance with the aperture ratio of the shutter element 3a in the period of 1 frame.

As a result, a feed-sequential type driving displayed in time division is performed on the emission light hr of red (R), the emission light hg of green (G), and the emission light hb of blue (B) in the period of 1 frame. Further, in parallel with that, the emission light hw of white (W) is displayed in the period of 1 frame.

Note that the light-emitting driving circuit 53′ sets a period during which the first scan line 13-1 on the first row to the first scan line 13-1 on the last row have been selected in the first period t1 to the third period t3 to a blank period tb. Moreover, a period during which the second scan line 13-2 on the first row to the second scan line 13-2 on the last row have been selected in the period of 1 frame is set to a blank period tb. Then, light emission in the light-emitting unit is stopped in the blank period tb. As a result, the blank period tb gives black display (Bk) in all the shutter elements 3a, and a transmission amount of each color in each row of the shutter element 3a is prevented from being different. Further, in the driving, portions corresponding to the two shutter elements 3a layered on the layered element EL1 and the single-layer element EL2 constitute sub pixels, respectively and these two shutter elements 3a become 1 pixel.

### Advantages of Second Embodiment

The display device 1′ configured as above has configuration in which the backlight panel 5′ in which the organic electroluminescence elements are provided so as to overlap the shutter element panel 3′ is provided and thus, size reduction and thinning of a frame can be achieved similarly to the display device of the first embodiment.

Moreover, similarly to the display device of the first embodiment, the single-layer element EL2 including the white light-emitting unit 57w in addition to the layered element EL1 including the red light-emitting unit 55r, the green light-emitting unit 55g, and the blue light-emitting unit 55b is provided as the organic electroluminescence element and thus, reduction of power consumption can be achieved similarly to the display device of the first embodiment.

### Modification of Second Embodiment

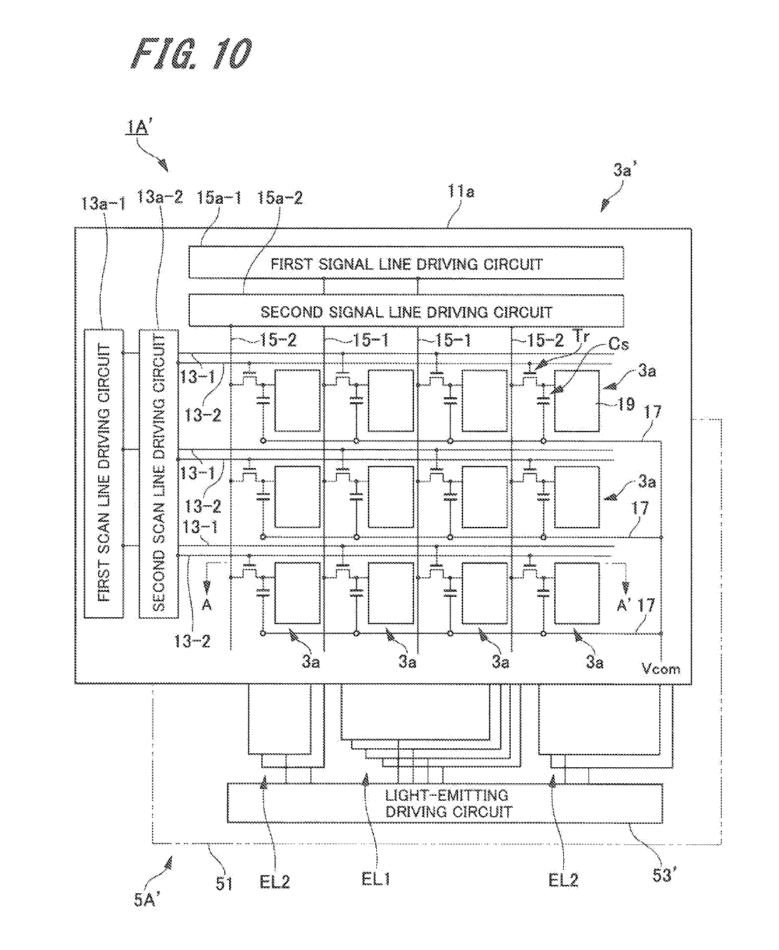

FIG. 10 is a schematic plan view of an essential part for explaining a modification of the second embodiment. A display device 1A′ illustrated in the figure is different from the display device 1′ in the second embodiment in configuration of a backlight panel 5A′. That is, in the backlight panel 5A′, the layered element EL1 is arranged as a common element between columns of the shutter elements 3a arranged adjacent to each other in the row direction and the single-layer element EL2 is arranged as a common element. In this case, the first signal line 15-1 and the second signal line 15-2 of one pair are wired by alternately switching arrangement, and if a first column has the order of the second signal line 15-2 and the first signal line 15-1, the subsequent column is arranged in the order of the first signal line 15-1 and the second signal line 15-2, and in the column subsequent to it, the order is switched in wiring. The other configuration is similar to that of the second embodiment including the connected state with the shutter element 3a and the driving method.

With the configuration of such modification, sizes of patterns of the layered element EL1 and the single-layer element EL2 can be increased, and miniaturization of the pixels can be handled more easily.

Note that, in the first embodiment, the second embodiment and their modifications above, the configuration using the organic electroluminescence element including the white light-emitting unit 57w as the single-layer element EL2 has been exemplified. However, the single-layer element EL2 is not limited to such configuration but may be those including a light-emitting unit which can obtain an emission light of a complementary color to an emission light of a simple color which can be obtained in the layered element EL1, for example. Even in such configuration, brightness of the entire display screen is improved, and the similar advantages can be obtained.

### REFERENCE SIGNS LIST

1, 1′, 1A, 1A′ display device
3a shutter element
3, 3′, 3A′ shutter element panel
5, 5′, 5A, 5A′ backlight panel
13 scan line
13-1 first scan line
13-2 second scan line
15 signal line
15-1 first signal line
15-2 second signal line
53, 53′ light-emitting driving circuit
55-1 first electrode (layered element)
55-2 second electrode (layered element)
55-3 third electrode (layered element)
55-4 fourth electrode (layered element)
55r red light-emitting unit
55g green light-emitting unit
55b blue light-emitting unit
57-1 first electrode (single-layer element)
57-2 second electrode (single-layer element)
57w white light-emitting unit
EL1 layered element (organic electroluminescence element)
EL2 single-layer element (organic electroluminescence element)

1. A display device comprising:
a light-transmitting shutter element panel in which shutter elements that control light transmission are arranged in a matrix; and
a backlight panel that has organic electroluminescence elements and that is arranged so as to overlap the shutter element panel, wherein
layered elements in which light-emitting units of different colors are sandwiched between a plurality of electrodes and single-layer elements in which a white light-emitting unit or a light-emitting unit of the complementary color of any of the different colors is sandwiched between a pair of electrodes are used as the organic electroluminescence elements; and
the layered elements and the single-layer elements are arranged so as to overlap the shutter elements in stripes that run parallel to a direction in which the shutter elements are arrayed.

2. The display device according to claim 1, wherein
a pair of the layered element and the single-layer element are arranged at each column of the shutter elements.

3. The display device according to claim 2, wherein
the layered element is arranged as a common element and the single-layer element is arranged as a common element, between the columns of the shutter elements arranged adjacent in a row direction.

4. The display device according to claim 2, wherein
the shutter element panel has a plurality of scan lines and a plurality of signal lines extended in a direction different from that of the scan lines;
each of the shutter elements is arranged at each of intersection portions between the scan lines and the signal lines in a state connected to these scan lines and signal lines;
the backlight panel has a light-emitting driving circuit connected to each electrode of the layered element and each electrode of the single-layer element; and
the light-emitting driving circuit sequentially causes the light-emitting units of different colors constituting the layered element and the light-emitting units constituting the single-layer element to emit light in accordance with selection of the shutter element by driving of the scan line.

5. The display device according to claim 1, wherein
with two columns of the shutter elements as a set, the layered element and the single-layer element are arranged at each of the two-column shutter elements.

6. The display device according to claim 5, wherein
the layered element is arranged as a common element and the single-layer element is arranged as a common element, between the columns of the shutter elements arranged adjacent in the row direction.

7. The display device according to claim 5, wherein
the shutter element panel has a plurality of pairs of first scan lines and second scan lines and a plurality of pairs of first signal lines and second signal lines extended in a direction different from that of the first scan lines and the second scan lines;
the shutter element arranged so as to overlap the layered element is arranged in a state connected to the first scan line and the first signal line at an intersection portion between the first scan line as well as the second scan line of the each pair and each of the first signal lines;
the shutter element arranged so as to overlap the single-layer element is arranged in a state connected to the second scan line and the second signal line at an intersection portion between the first scan line as well as the second scan line of the each pair and each of the second signal lines;
the backlight panel has a light-emitting driving circuit connected to each electrode of the layered element and each electrode of the single-layer element; and
the light-emitting driving circuit sequentially causes the light-emitting units of different colors constituting the layered element to emit light in accordance with selection of the shutter element by driving of the first scan line and causes the light-emitting unit constituting the single-layer element to emit light in accordance with selection of the shutter element by driving of the second scan line.
